(19) United States
(12) Patent Application Publication
(10) Pub. No.: US 2005/0105071 A1
(43) Pub. Date: May 19, 2005

(54) Methods for patterning substrates having arbitrary and unexpected dimensional changes

(76) Inventor: Fusao Ishii, Menlo Park, CA (US)

Correspondence Address: WAGNER, MURABITO & HAO LLP, Two North Market Street, Third Floor, San Jose, CA, 95113, US

(21) Appl. No.: 10/814,082

(22) Filed: Mar. 30, 2004

Related U.S. Application Data
(60) Provisional application No. 60/475,801, filed on Jun. 3, 2003.

(51) Int. Cl. G03B 27/62; G06F 17/50; G03B 27/42; G03B 27/58; G06F 9/45; G03F 9/00

(52) U.S. Cl. 355/53; 355/47; 716/1; 716/19; 716/8

(57) ABSTRACT

Methods for patterning a plurality of electronic elements on a deformable substrate. The method uses an optical measurement device for optically measuring an existing geometric pattern on a substrate. The existing pattern is written on an n^{th} layer of the substrate. A computing device, coupled to the optical measurement device, calculates a correction between the existing geometric pattern and an expected pattern for the n^{th} layer. An image transformation component, coupled to the computing device, performs an image transformation on an electronic pattern to be used in an (n+1)^{th} layer, based on the calculated correction, to generate a corrected electronic pattern. A writing component, coupled to the image transformation component, writes the corrected electronic pattern onto the (n+1)^{th} layer using a programmable digital mask system. The writing component contains a radiation source which is coupled to an optical system for guiding radiation from the radiation source to the programmable digital mask and from there to the substrate.

### RELATED U.S. APPLICATION

This Application claims priority to the copending provisional patent application Ser. No. 60/475,801, Attorney Docket Number SONY-50T5470.PRO, entitled “Exposure Systems and Methods Suitable for Patterning Substrates with Arbitrary and Unexpected Dimensional Changes,” with filing date Jun. 3, 2003, assigned to the assignee of the present application, and hereby incorporated by reference in its entirety.

This Application is related to U.S. Patent Application by Fusao Ishii entitled “System for Fabricating Electronic Modules on Substrates Having Arbitrary and Unexpected Dimensional Changes” with attorney docket no. SONY-50T5469, Ser. No. ______, filed concurrently herewith, and assigned to the assignee of the present invention, hereby incorporated by reference in its entirety.

### FIELD OF THE INVENTION

An embodiment of the present invention relates to a system for fabricating electronic modules on substrates that have arbitrary and unexpected dimensional changes. Such systems find application in fabricating electronic modules, e.g., electronic modules found in displays and semiconductor devices.

### RELATED ART

Significant advances have been made in photolithography systems. In step-and-repeat exposure systems (steppers), the total substrate area to be patterned is divided into several fields that are imaged, one at a time, by stepping the substrate under a projection optical system from one field to the next. It is important that the mask and wafer be properly aligned to each other. Alignment between the mask and the wafer comprises global (or inter-field) alignment and alignment within a field (intra-field alignment). Conventional art includes a method of performing explicit inter-field and intra-field alignment in a step-and-repeat system involving alignment marks placed in unexposed areas between adjacent fields called “streets.”

Since the streets contain no patterns, there is no requirement to precisely stitch together adjacent fields. For many important applications, such as flat panel displays, it is necessary to obtain large, patterned areas. Adjacent fields must be stitched together with great precision. One prior art method accomplishes this by providing a polygonal image field and complementary exposures in overlap regions between adjacent scans in such a way that seam characteristics of adjacent scans are absent and the cumulative illumination dose over the entire substrate is uniform. This exemplary conventional embodiment includes a system for aligning each chip, where each chip is separated from adjacent chips by unpatterned areas. Numerous improvements to the scan-and-repeat system of have been proposed. For example, one conventional system is a 1:1 (unity magnification) exposure system that comprises an integrated stage assembly for both mask and substrate. In such a system, an integrated stage assembly is provided for both mask and substrate. It does not provide any means for fine adjustment in magnification (deviation from 1:1 magnification) to compensate for slight changes in substrate dimensions. However, it is known that substrate dimensions can change due to thermal or chemical processing steps.

Another conventional system provides an improved exposure beam geometry that can accommodate a photosensitive substrate with non-linear exposure characteristics. This non-linearity arises from the fact that the photosensitivity of the substrate does not add linearly with light intensity. In another conventional system, an improvement to the aforementioned 1:1 scan-and-repeat exposure system handles roll-fed flexible substrates. In this case, each field is held rigidly on a fixed support.

Yet another conventional system provides optical and mechanical compensation for slight changes in substrate dimensions. The mechanical compensation means comprises auxiliary stages that provide a differential relative velocity between the mask and substrate. The optical compensation means comprises an improved optical system that can provide fine adjustment of magnification in the x and y directions. These compensation means are useful for providing global adjustments in accordance with changes to substrate dimensions in the x and y directions. However, it cannot make local changes from field to field.

A substrate can undergo distortions and changes in its dimensions. Another conventional exposure system and method exists that accounts for warped substrates. A warped substrate is one that has substantial deviation from flatness. This warping is accounted for by alignment marks being placed at the periphery of the substrate and focus marks placed throughout the substrate, including the periphery of the substrate, near the alignment marks. When the optical system is brought into focus for exposure, all of the focus marks are used. However, when the optical system is brought into focus for substrate alignment (translation, rotation, inclination), only the focus marks at the periphery of the substrate close to the alignment marks are used. This system is primarily concerned with deformation of the substrate perpendicular to the plane of the substrate and, therefore, does not address the problem of local or global expansion/contraction of the substrate primarily within the plane.

Another conventional exposure system can pattern substrates with a wide range of curvatures. Here, optical detection means are provided to dynamically measure the height of the substrate, and the area of the substrate being patterned is always kept within the depth of focus of the imaging continually adjusting the height of the substrate to configure the focal plane of the projection optics to be at the height of the substrate. This system is primarily concerned with deformation of the substrate perpendicular to the plane of the substrate and, therefore, does not address the problem of local or global expansion/contraction of the substrate primarily within the plane.

Using conventional alignment techniques, circuit structures for flexible circuits, “flex circuits,” can generally obtain a spacing of 25 microns line width leading to a wire pitch of 50 microns. It would be desirable to reduce this pitch size to lead to higher density flex circuits.

### SUMMARY OF THE INVENTION

Embodiments of the present invention provide a method for creating electronic modules, such as displays and semiconductor devices, that can be fabricated at low cost on a variety of substrates including flexible printable circuit (FPC) plastics, metals, ceramics, paper, and glass. In one embodiment, the system can be used in the manufacture of high density flex circuits. As a result, it is possible to produce modules of large area at low cost. Fabrication of such modules is enabled by improved lithography systems and methods. The improved lithography system uses a programmable mask mechanism, such as a digital micro-mirror device (DMD) array. As a result, the mask pattern can be modified almost instantaneously, in real time, to account for physical variations or deviations of a mask pattern on the substrate relative to its expected or ideal pattern.

A method for patterning a plurality of electronic elements on a substrate is disclosed in accordance with one embodiment of the present invention. As discussed below, the method uses an alignment mechanism containing an optical measurement system and an electronic programmable digital mask system. The method also utilizes an optical measurement device for optically measuring an existing geometric pattern, corresponding to an exposed mask pattern, on a substrate. The existing pattern is written on an nth layer of the substrate. A computing device, coupled to the optical measurement device, calculates a correction between the existing geometric pattern of the substrate and an expected pattern for the nth layer. An image transformation component, coupled to the computing device, performs an image transformation on a mask pattern intended for an (n+1)^{th} layer, based on the calculated correction, to generate a corrected pattern. A writing component, coupled to the image transformation component, writes the corrected pattern onto the (n+1)^{th} layer using a programmable digital mask system. The writing component contains a radiation source. An optical system is coupled to the writing component for guiding radiation from the radiation source to the programmable digital mask and from the programmable digital mask to the substrate. In this way, the corrected pattern for the (n+1)^{th} layer can be written onto the substrate with high alignment accuracy to the n^{th} layer mask.

In one embodiment, the radiation source may contain a pulsed laser source having inter-pulse intervals. In another embodiment, the radiation source is infrared light. In other embodiments, the radiation source may be ultraviolet light, x-ray, or visible light.

The image transformation may, in one embodiment, be performed via a linear coordinate transform or, in another embodiment, via a non-linear spline function.

The programmable digital mask system can be of any technology allowing for an array or field of programmable modulated elements such as, according to one embodiment, an array of digital micro-mirror devices. In one embodiment, the system of the present invention may be used to achieve wire pitch of 1-10 microns for the production of high density flex circuit devices.

### BRIEF DESCRIPTION OF THE DRAWINGS

The accompanying drawings, which are incorporated in and form a part of this specification, illustrate embodiments of the invention and, together with the description, serve to explain the principles of the invention:

FIG. 1 is a flow chart for a typical process followed in the fabrication of an array of amorphous silicon thin film transistors (TFTs) that may be employed in accordance with one embodiment of the present invention.

FIG. 2 illustrates a section of a substrate containing a plurality of global alignment segments in accordance with one embodiment of the present invention.

FIG. 3 is a schematic diagram illustrating details of a global alignment segment in accordance with one embodiment of the present invention.

FIG. 4 is a schematic diagram illustrating a geometric deviation of a global alignment segment in accordance with one embodiment of the present invention.

FIG. 5 is a schematic diagram illustrating an exposure system in accordance with one embodiment of the present invention.

FIG. 6 is a schematic representation of an example of overlapping exposure areas in accordance with one embodiment of the present invention.

FIG. 7 is a schematic representation of non-overlapping exposure areas in accordance with one embodiment of the present invention.

FIG. 8 is a schematic representation of a target mask pattern and an existing previous mask pattern for which image transformations may be performed in accordance with one embodiment of the present invention.

FIG. 9 is a flow diagram summarizing a method for fabricating a circuit on a substrate, in accordance with one embodiment of the present invention.

FIG. 10 is a block diagram of an exemplary computer system upon which embodiments of the present invention may be practiced.

### DETAILED DESCRIPTION OF THE INVENTION

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the present invention, numerous specific details are set forth in order to provide a thorough understanding of the present invention. However, it will be obvious to one of ordinary skill in the art that the present invention may be practiced without these specific details. In other instances, well-known methods, procedures, components, and circuits have not been described in detail so as not to unnecessarily obscure aspects of the present invention.

Embodiments of the present invention are particularly useful in the production of large area electronic modules such as flat panel displays (FPDs) and can be used on the fabrication of deformable-substrate based integrated circuits such as flexible printed circuits (FPCs). A conventional FPD may be a liquid crystal display (LCD) wherein each pixel is driven by a thin film transistor (TFT). Typically the semiconductor in a TFT is amorphous silicon (a-Si) or polycrystalline silicon (p-Si). Advanced TFT fabrications are the so-called 5th generation fabrications, which use glass substrates with dimensions exceeding 1 meter on each side. There is a continuing interest in using larger glass substrates because of the enhanced productivity. However, the increased glass size is accompanied by challenges in glass substrate transport and processing. For this reason, there is substantial interest in replacing piece-by-piece processing of glass substrates with roll-to-roll processing of flexible, or deformable, substrates.

LCD panels that measure more than 20″ diagonally are becoming increasingly popular for desktop monitors and LCD TVs. Such panels have substrates measuring at least 41 cm by 31 cm. All TFTs and passive elements in these areas require fabrication with excellent overlay accuracy.

Thermal expansion and contraction of glass substrates is an important consideration. For instance, one widely used glass substrate is Corning 7059, which has a CTE (coefficient of thermal expansion) of 4.6 ppm per ° C. at 20° C. This means that an unexpected temperature rise of 10° C. may cause a 1 m wide glass substrate to expand by 46 mm. For example, temperature deviations may occur because of changes in the ambient temperature or heating of the exposure system from the exposure light source. Unexpected substrate dimensional changes present a challenge for the overlay accuracy of the photolithography system, especially as the size of large area electronic modules increases.

Thermal properties of glass (Corning 7059) are compared to other popular substrate materials in Table 1 below. Many conventional (analog) masks are fabricated on quartz, which has a significantly lower CTE than glass. The more expensive substrate materials, which are generally not used for large area electronic modules, have higher CTE values than glass.

TABLE 1

| Substrate Material | CTE (ppm/° C.) |
|---|---|
| Glass (Corning 7059) | 4.6 |
| Fused Quartz | 0.4 |
| SiC (6H) | 10.3 |
| Sapphire Al₂O₃ | 3.24-5.66 |
| GaAs | 6.86 |
| Si | 2.6 |

Glass substrates also exhibit irreversible changes in dimensions after annealing. A 2-hour thermal anneal at 550° C. results in an irreversible contraction of up to 120 ppm. In the production of p-Si TFTs, thermal annealing in the range of 450 to 550° C. is required.

An alternative to piece-by-piece processing of glass substrates is roll-to-roll processing on flexible substrates. U.S. Pat. No. 5,652,645, issued Jul. 29, 1997 and incorporated herein by reference, discloses a photolithography system that can process roll-fed flexible substrates. Roll-to-roll processing may become an attractive approach for increasing productivity. Potential flexible substrate materials include metals and plastics. Thermal properties of representative metal and plastic materials are tabulated in Table 2 below.

TABLE 2

| | Glass Transition | Melt Temp | |
|---|---|---|---|
| Material | Temp (° C.) | (° C.) | CTE (ppm/° C.) |
| Al alloy (6061-T4) | | 582-652 | 23.6 |
| Cu, annealed | | 1083 | 16.4 |
| Stainless Steel | | 1400 | 17.3 |
| (AISI 304) | | | |
| Polyimide (PI) | 330 | | 45-90 |
| Polycarbonate | 205 | | 70 |
| (PC) | | | |
| Polyethersulfone | 223 | | 31-70 |
| (PES) | | | |
| Polysulfone | 190 | | 55-100 |

Metal substrates have sufficiently high melting temperatures to be able to withstand thermal anneal steps. However, a drawback to metal substrates is that they are opaque and are not suitable for transmissive LCDs. Therefore, transfer processes are being developed in which TFT arrays are initially fabricated on metal substrates, separated from the substrate, and then transferred to transparent substrate to make a transmissive display. Another characteristic of the representative metal substrates is that their CTE values are all substantially greater than that of glass. This means that lithographic processing of large area electronic modules on metal substrates will encounter greater challenges with substrate dimensional changes.

Many representative plastic substrates cannot withstand thermal annealing greater than 200° C. However, it is desired to adopt plastic for roll-to-roll processing because of its optical transparency and low cost. An important drawback to plastic substrates is that their CTE values have a large variability. This means that there may be significant variation in substrate dimensional changes from location to location on the same roll and from batch to batch. Furthermore, plastic substrates exhibit irreversible shrinkage upon thermal annealing. For example, polycarbonate (PC) shrinks irreversibly by 10² ppm after annealing at 130° C. for 1 hour. Similarly, polyethersulfone (PES) shrinks irreversibly by 10² ppm after annealing at 200° C. for 1 hour. Therefore, plastic substrates may exhibit arbitrary and unexpected dimensional changes.

The systems and methods of the present invention provide alignment mechanisms that are applicable to a wide variety of substrate materials including metals, plastics, ceramics, paper, and glass and for arbitrary dimensional changes. Embodiments are particularly useful on deformable substrates such as flexible printed circuits (FPCs). Dimensional changes may result from thermal factors as discussed above or from other factors, such as mechanical means. For example, a roll of plastic substrate may be stretched in a particular direction during a process step, because plastic substrates have high elasticity.

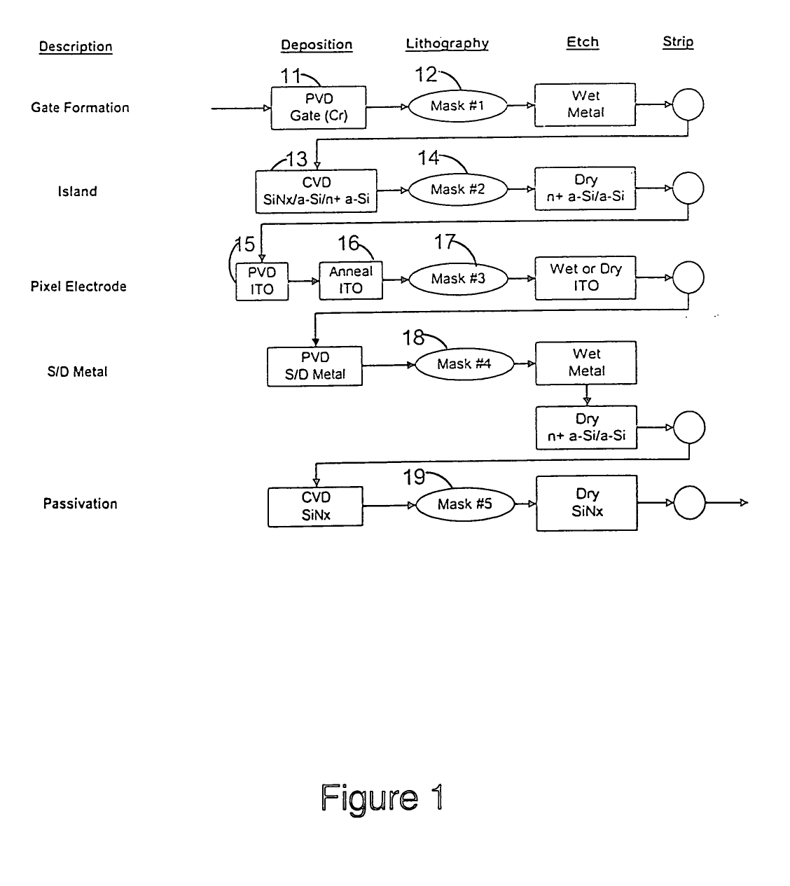

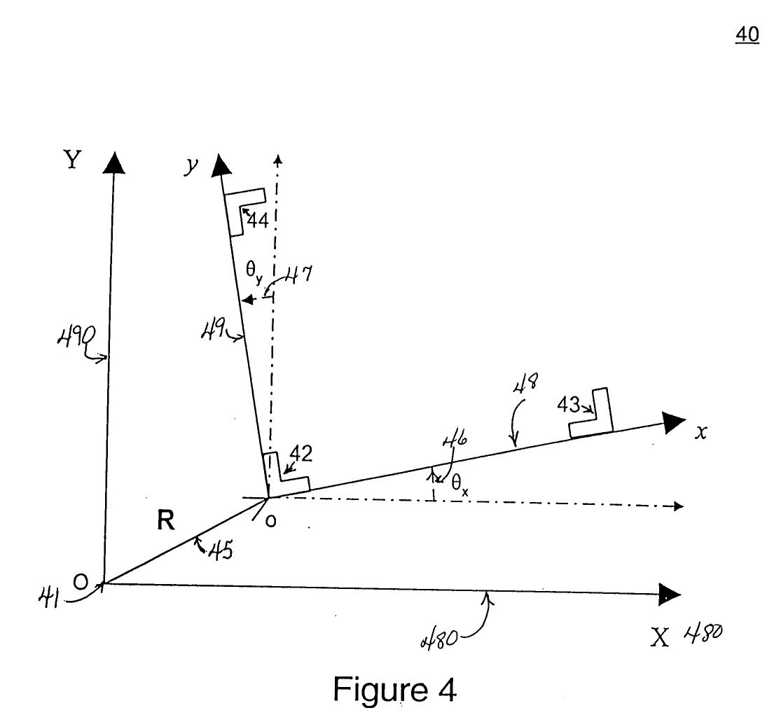

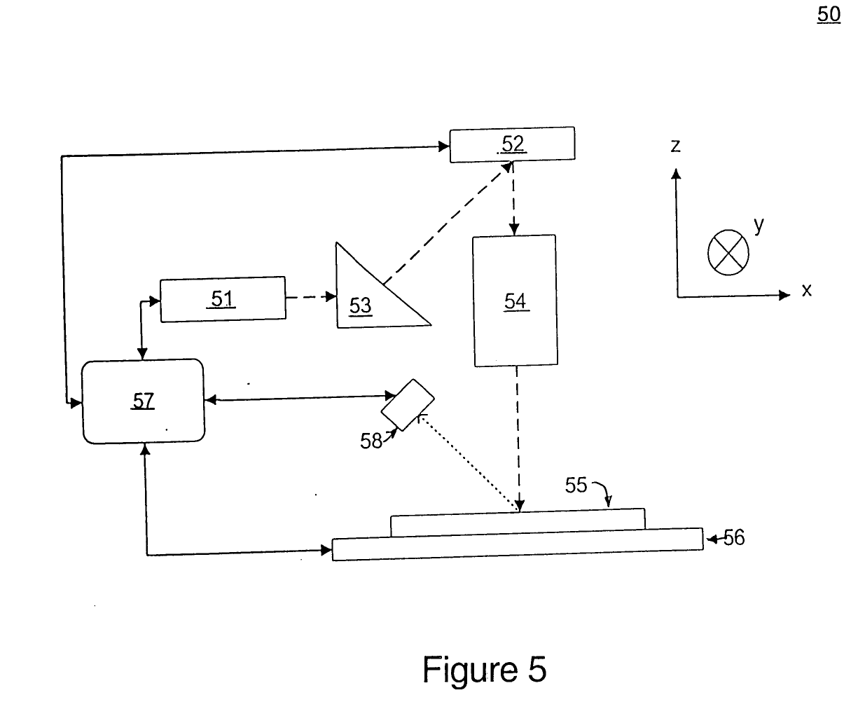

One embodiment of the present invention is described in detail with a process for the fabrication of a-Si TFTs in a roll-to-roll process on flexible substrates. Flexible, or deformable, substrates may include such materials as plastic, metal, paper, ceramic, glass, or any material that may be deemed desirable as a substrate on which to form electronic elements. FIG. 1 shows the overall process flow 10 for the fabrication of an a-Si TFT array that may be employed by an embodiment of the present invention. The TFT structure is a bottom gate, staggered structure in which the gate is located below the semiconductor channel and the source/drain electrodes are located above the semiconductor channel. A substrate is optionally provided with a buffer layer. In the case that the substrate is a metal, the buffer layer provides electrical insulation and protects the substrate against corrosion. In the case that the substrate is a plastic, the buffer layer is a barrier against oxygen and moisture. In step 11, the gate metal (e.g. Cr) may be deposited on the substrate by sputtering, and in step 12, gate electrodes and gate lines are patterned by the 1st photolithography step. In step 12, global and local alignment marks are also patterned. These alignment marks comprise the same material (e.g. Cr) as the gate electrodes and lines but may not necessarily perform any electrical functions. FIG. 1 will be discussed further in conjunction with FIGS. 4 and 5 below.

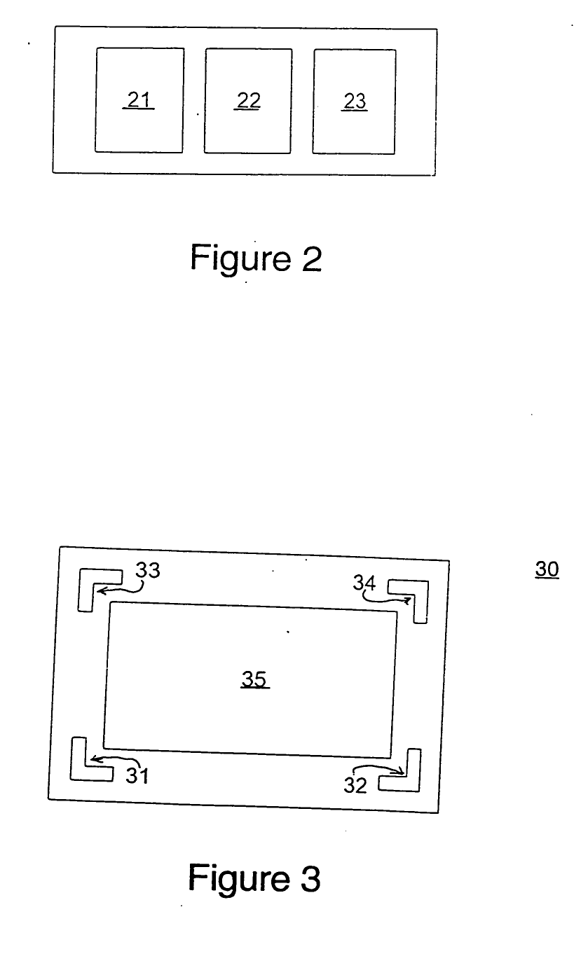

FIG. 2 illustrates a section 20 of an exemplary roll of substrate material containing a plurality of global alignment segments in accordance with one embodiment of the present invention. The section of substrate material has been divided into several global segments 21, 22, 23, each of which may be fabricated into a distinct electronic module in accordance with one embodiment. In this case, the electronic module may be an exemplary TFT array for a flat panel display. Each global segment 21, 22, 23 comprises an area over which a global alignment of the exposure system is to be carried out. Within each global segment, it is necessary to achieve excellent alignment of a layer to all preceding layers to obtain high density results. For example, for the fabrication of bottom gate, staggered a-Si TFT arrays, it is important to precisely align the source/drain electrodes of each TFT with the underlying gate electrode. On the other hand, precise alignment between adjacent global segments 21, 22, 23 is not critically important. In this example, after the fabrication of a TFT array on the substrate, the substrate is cut into individual display back planes using the space between the global segments 22, 23, 24 as the kerf.

FIG. 3 is a schematic diagram illustrating details of an exemplary global alignment segment 30 in accordance with one embodiment of the present invention. Global segment 30 comprises global alignment marks 31, 32, 33, and 34, and a region 35 in which the TFT array is fabricated. This is how a global segment may appear after completing the 1st photolithography step (e.g., step 12 of FIG. 1). Global alignment marks 31, 32, 33 and 34 may be located anywhere in the global segment. However, it may be preferable to position the global alignment marks at the periphery of the global segment. This enables the global alignment system to detect and locate the global alignment marks in future photolithography steps.

Referring again to FIG. 1, in accordance with one embodiment of the present invention a next step in TFT array fabrication is step 13. In step 13 the three layers of SiNₓ, a-Si:H, and n⁺ a-Si may be deposited in a continuous process by PECVD (plasma enhanced chemical vapor deposition) without breaking vacuum. In this case, the SiNₓ layer functions as the gate dielectric, the a-Si:H layer is the semiconductor channel, and n⁺ a-Si forms a low resistance contact to the source/drain electrode metals. Some of the energy for converting SiH₄ and NH₃ to a-Si:H is provided by the plasma; however, the process raises the substrate temperature to 180° C. Therefore, this process may cause some arbitrary dimensional changes to the substrate. In step 14 of FIG. 1, a second photolithography step is carried out to pattern the a-Si islands.

According to one embodiment, during the 2nd photolithography step 14, segments of the substrate are placed on prescribed locations on the substrate stage. A detection device, e.g., an optical detection device, detects the positions of the global alignment marks in each global segment. FIG. 4 shows a coordinate system 40 of a global segment according to one embodiment of the present invention. The detection device locates alignment marks 42, 43, and 44. A vector between global alignment mark 42 and 43 may be determined and forms the x-axis 48 of the global segment. Similarly, a vector between alignment marks 42 and 44 form the y-axis 49 of the global segment. The x and y axes intersect at the origin 41 (O). It should be noted that other methods of establishing x-axis 48 and y-axis 49 are possible and more than 3 global alignment marks may be used.

As a result of substrate deformation, the location of the global segment may have changed since the global alignment marks were patterned on the substrate in the 1 st photolithography step. The original location of the global segment is shown by the coordinate system 40 with X-axis 480 and Y-axis 490 meeting at the origin O 41. The location of the coordinate system 40 is calculated relative to known reference positions such as an edge or corner of the substrate or the positions of other global segments. There is a displacement vector R 45 between the two coordinate systems. The angle Θₓ 46 describes the angle of rotation of the x-axis 48 relative to the X-axis 480. The angle Θ_{y} 47 describes the angle of rotation of the y-axis 49 relative to the Y-axis 490. When the global alignment marks were patterned on the substrate, the X- and Y-axes, 480 and 490 were configured to be orthogonal. However, the x- and y-axes 48 and 49 are not necessarily orthogonal.

The detection device detects substrate dimensional changes. As initially patterned in step 11, the distance on the substrate between alignment mark 42 and 43 was Lₓ and the distance on the substrate between alignment mark 42 and 44 was L_{y}. However, during the global alignment process in step 12, it may be found that the distance on the substrate between alignment mark 42 and 43 is now Lₓ+δₓ where δₓ is a real number. Similarly, it is found that the distance on the substrate between alignment mark 42 and 44 is now L_{y}+δ_{y} where δ_{y} is a real number. Generally, |δₓ|<<Lₓ and |δ_{y}|<<L_{y}. The desired magnification correction along the x-axis is δₓ/Lₓ and that along the y-axis is δ_{y}/L_{y}. Using the above measurement technique, the present invention can determine the amount of variation of the alignment marks due to substrate deformation.

U.S. Pat. No. 6,312,134, filed Nov. 6, 2001 and incorporated herein in its entirety, has described the integration of a digital micro-mirror device (DMD) array into an exposure system. As discussed in more depth below, one embodiment of the present invention utilizes a programmable digital mask, e.g., DMD, to expose a second mask pattern that has been corrected based on alignment deviations detected by the detection device. These corrections are in turn based on substrate deviations of the fabrication process. Since the deformation detection and measurement can be done in real-time, the correction and exposure of the corrected pattern can also be done in real time. An exposure system in accordance with the one embodiment of the present invention is described with reference to FIG. 5.

FIG. 5 is a schematic illustration of an exposure system 50 in accordance with an embodiment of the present invention. The output beam from a radiation source 51 illuminates a spatial light modulator array array 52, which, for purposes of example, is a digital micro-mirror device (DMD). A DMD is an array of micro-mirrors on a chip with associated electronic logic, memory, and control that enable the individual mirrors to modulate, e.g., tilt, in different directions for selective reflection or deflection of individual pixels. It should be understood that the programmable mask can be accomplished using any programmable spatial light modulator, e.g., a liquid crystal light valve array, DMD, etc. The radiation source may be, in one embodiment, a pulsed laser having inter-pulse intervals, or it may be an unpulsed laser source. In other embodiments, the radiation source may be any one of visible light, ultra-violet light, infrared light, or x-rays, or any other form of radiation that may be used to expose a pattern onto a substrate. As needed, an optical system 53 is provided to guide the beam from the radiation source 51 to the programmable spatial modulator, e.g., DMD array 52. Similarly, as needed, an optical system 54 is provided to guide the beam from the DMD array 52 to the substrate 55. Optical systems 53 and 54 generally include lenses, mirrors, and beam splitters and are known to those skilled in the art.

According to one embodiment, a substrate 55 is positioned on the substrate stage 56 and is scanned along an axis, e.g., the y-axis. Control system 57 feeds a stream of pixel selection data to DMD array 52, thus causing the micro-mirrors to modulate appropriately to form a mask pattern therein. The illuminated pixel pattern imaged onto the substrate by the radiation source represents an instantaneous snapshot of the set of micro-mirrors at that time. In order to ensure that the pattern imaged onto the substrate is not blurred, the pixel selection data stream configuring the DMD array 52 is synchronized with the motion of the scanning stage. The radiation illuminating the DMD array 52 is pulsed or shuttered at a repetition rate that is synchronized with the micro-mirrors on DMD array 52 and scanning stage 56. Each time that the DMD array 52 is illuminated, the DMD pixels are reset to generate a different pattern and the scanning stage 56 is moved. After completing a scan along the y-axis, stage 56 is moved a suitable distance along the x-axis, and another scan along the y-axis is started.

In FIG. 5, solid lines are used to indicate control and data signals, dashed lines indicate the propagation direction of the radiation from the radiation source 51, and the dotted line indicates the probe optical signal for the detection device 58.

The global alignment procedure of one embodiment of the present invention is now described with reference to FIGS. 4 and 5. According to one embodiment, the detection device 58 measures the positions of the global alignment marks on substrate 55 which may be associated with an exposed first mask pattern, pattern (n). These positional data are sent to the control system 57. Control system 57 receives, from a storage device or a memory device, the mask pattern data that were used to pattern the global alignment marks on substrate 55. Control system 57 compares these mask pattern data and the present global alignment mark position data and calculates displacement, rotational, and magnification deviation information. This deviation information is collectively referred to as geometrical deviation information. Geometrical deviation information may be expressed in terms of the displacement vector R 45, rotations Θₓ 46 and Θ_{y} 47, and magnification corrections δₓ/Lₓ and δ_{y}/L_{y}. Other parameters may be used to express displacement, rotational, and magnification deviation and are well known in the art. It should be understood that geometrical deviation information includes more than displacement deviation information. Based on the geometrical deviation information, the control system 57 may optionally instruct the substrate stage 56 to move to a new location such that the deviations R 45, Θₓ 46, and Θ_{y} 47 are reduced. This may be a possible and desirable optimization provided the substrate stage has a means to accomplish fine positional adjustments.

Still referring to FIGS. 4 and 5, according to one embodiment, control system 57 also receives, from a suitable source such as a storage device, an initial mask pattern for the 2nd photolithography step. Herein, this initial mask pattern is the (n+1)^{th} pattern. The control system 57 does not configure the DMD array 52 with this initial mask pattern. Instead, control system 57 modifies the initial mask pattern electronically in response to the global alignment deviation information. The control system calculates data to modify the initial mask pattern to take the following into account: 1) the displacement of the global segment R 45; 2) the rotation of the global segment Θₓ 46 and Θ_{y} 47; and 3) the magnification correction δₓ/Lₓ and δ_{y}/L_{y}. What is produced is a modified initial mask pattern that is fed to the DMD array 52 for imaging and exposure.

In accordance with one embodiment, the mask pattern data for the second photolithography step may include global alignment marks that correspond to the global alignment marks for the 1 st photolithography step. The mask pattern data for the second photolithography step are modified in such a manner that their global alignment marks are better aligned to the corresponding global alignment marks on the substrate segment for the 1st photolithography step.

According to one embodiment of the present invention, the alignment of patterns that are generated in the second photolithography step using the modified initial mask pattern to the patterns that exist on the same substrate segment from the first photolithography step is improved over the alignment of patterns that are generated in the second photolithography step using the unmodified initial mask pattern to the patterns that exist on the substrate segment from the first photolithography step. This may occur even though the alignment of the modified initial mask pattern of the second photolithography step to the mask pattern of the first photolithography step may be inferior to the alignment of the initial mask pattern of the second photolithography step to the mask pattern of the first photolithography step.

Referring once again to FIG. 1, upon completing the a-Si islands, formed by mask #2 at step 14, the pixel electrode is formed. Since this a-Si TFT array is intended for use in a transmissive LCD, the pixel electrode may be ITO (indium tin oxide), which is a transparent conductor. The ITO layer is formed by a sputtering step 15 and the substrate temperature generally exceeds 200° C. This is followed by a thermal anneal step 16 which reduces the electrical resistivity of ITO. Thermal anneal temperatures are typically in the 300° C. to 450° C. range. Steps 15 and 16 are also noted for the possibility of inducing substrate deformations. A 3rd photolithography step (step 17) is carried out to pattern the pixel electrode. After the pixel electrode, the source/drain electrodes/lines and passivation layers are formed. The passivation layer is typically SiNₓ which is deposited by PECVD. There are two additional photolithography steps including an S/D metal step 18 and a passivation step 19.

The performance of a highly dense TFT is dependent upon the alignment among the gate, the semiconductor channel, and source/drain electrodes. Therefore, an important objective of the present invention is to achieve superior local alignment. Local alignment means the alignment of a feature in a layer to corresponding features in adjacent layers, e.g., from mask to mask.

The local alignment procedure is explained, according to one embodiment, with reference to the 2nd photolithography step (step 14) in FIG. 1. The local alignment procedure is optionally carried out after the global alignment procedure. The control system may divide each global segment into one or more local alignment regions. Each local alignment region should contain at least three local alignment marks. A local alignment mark may be a global alignment mark that is located in the local alignment region, or a mark provided for local alignment. A local alignment mark may comprise an active portion of the patterned electronic module or may serve no function other than for alignment. In this example, a local alignment mark may be a particular gate electrode. Gate electrodes are patterned in the first photolithography step.

Referring now to FIGS. 1 and 5, in order to carry out local alignment in a particular local alignment region, the control system (e.g., 57 of FIG. 5) receives mask pattern data from the first photolithography step (12 of FIG. 1) corresponding to the local alignment, according to one embodiment. The mask pattern data includes positional information for the local alignment marks, which are selected gate electrodes in this example. The detection device 58 measures the positions of the local alignment marks (selected gate electrodes) on substrate 55. These positional data are sent to the control system 57. Control system 57 compares these mask pattern data and the present local alignment mark position data and automatically calculates geometrical deviation information in the local alignment region. Information obtained from the global alignment procedure may be useful for locating local alignment marks.

The control system 57 also receives, from a suitable source such as a storage device, an initial mask pattern for the 2nd photolithography step. The control system 57 does not configure the DMD array 52 with this initial mask pattern. Instead, control system 57 modifies the initial mask pattern in response to the geometrical deviation information in the local alignment region to produce a modified mask pattern which may be stored in memory.

The mask pattern for the second photolithography step includes pattern information about a-Si islands. It is desirable to improve the alignment of a-Si islands to their corresponding gate electrodes. Selected gate electrodes have been designated as local alignment marks. Therefore, selected a-Si islands that correspond to the selected gate electrodes are designated as local alignment marks according to an embodiment of the present invention.

The initial mask pattern data are modified such that their local alignment marks for the second photolithography step are better aligned to the corresponding local alignment marks on the substrate segment for the 1 st photolithography step. The modified mask pattern is fed to the DMD array 52 for imaging and exposure thereof.

Typically each substrate segment is divided into a plurality of exposure areas. The exposure areas may have different shapes depending on the exposure system and method. U.S. Pat. No. 6,312,134 provides for seamless scanning by complementary overlapping polygonal scans to equalize radiation dose and may be used in accordance with an embodiment of the present invention.

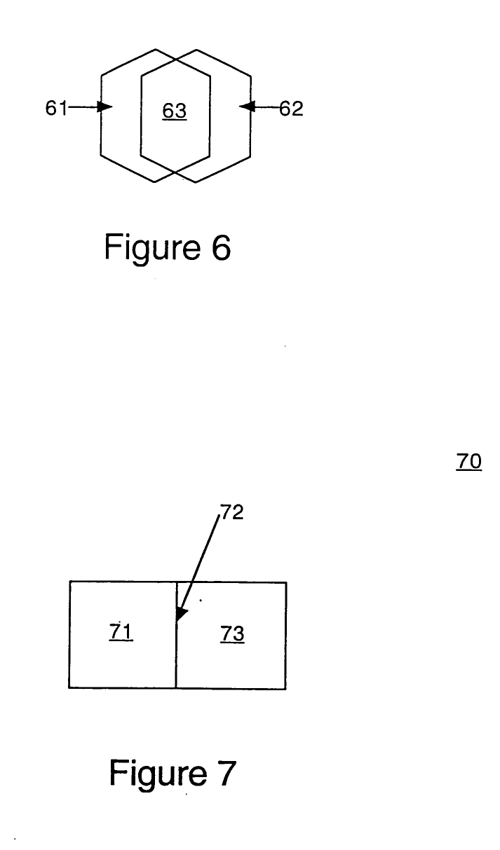

In one embodiment, the polygon is a hexagon. An example of hexagonal scans 60 are shown in FIG. 6 in accordance with one embodiment of the present invention. FIG. 6 shows two adjacent hexagonal scan areas 61 and 62. It is possible for local alignment regions to overlap. For example, regions 61 and 62 may comprise two local alignment regions. However, since there is an overlap region 63, the modified mask pattern for region 61 and the modified mask pattern for region 62 should be made to be substantially identical in the overlap region 63. In this case, the term “substantially identical” means that any discrepancies in the mask patterns are small enough that blurring of the resulting pattern is less than a small and generally predetermined threshold value.

FIG. 7 is a schematic representation of non-overlapping exposure areas in accordance with one embodiment of the present invention. An exposure area geometry 70 is shown in FIG. 7 in which two adjacent exposure areas 71 and 73 do not overlap. There is a boundary line 72 between the adjacent exposure areas. In another embodiment, regions 71 and 73 may also comprise two local alignment regions. Modified mask patterns must be generated such that there is a seamless stitching of patterns at boundary 72.

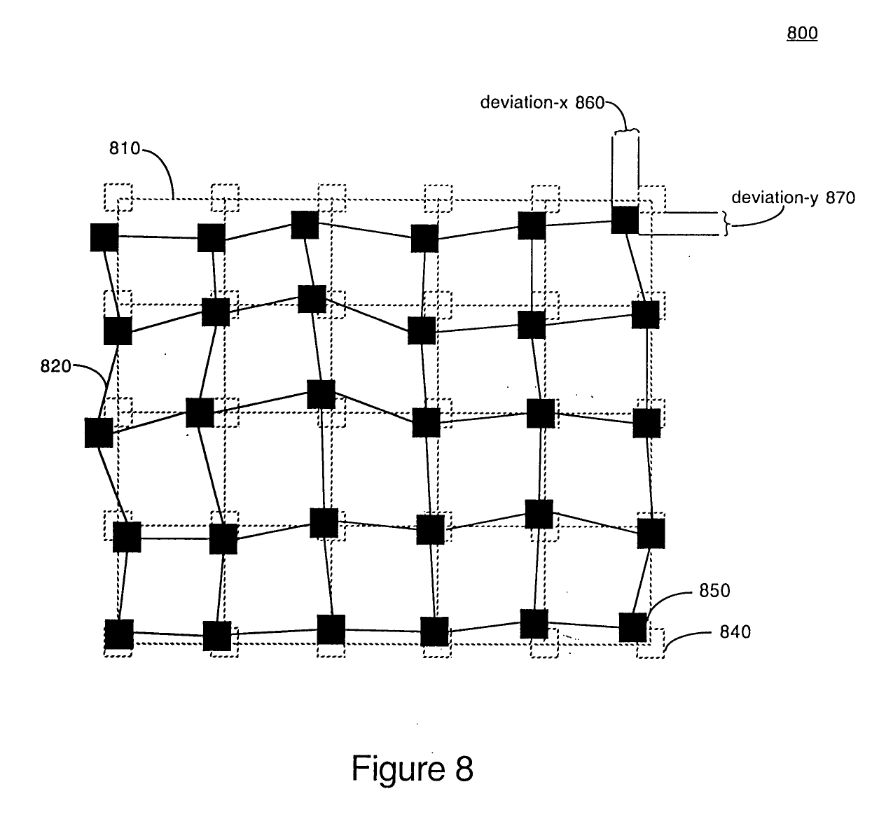

FIG. 8 is a schematic representation of an exemplary target mask pattern 810, represented by dotted lines, and an existing pattern 820, represented by solid lines, of features resulting from a photolithography step applying target pattern 810 followed by processing, for which image transformations may be performed in accordance with one embodiment of the present invention. Single exposure regions that exist on the substrate are shown as dark squares, such as region 850. The target pattern for region 850 at the same location is indicated by feature 840. In order to perform the next photolithography step, the deviation of each feature from its target pattern is determined, such as deviation-x 860 and deviation-y 870, and a correction is calculated that is subsequently applied to the pattern of the next photolithography step so as to reduce the deviation between successive photolithography steps.

In the present embodiment, an appropriate method for reducing the deviation may be applying a non-linear coordinate transformation, such as a spline function, in a single exposure region with multiple polygons formed by multiple adjacent alignment marks.

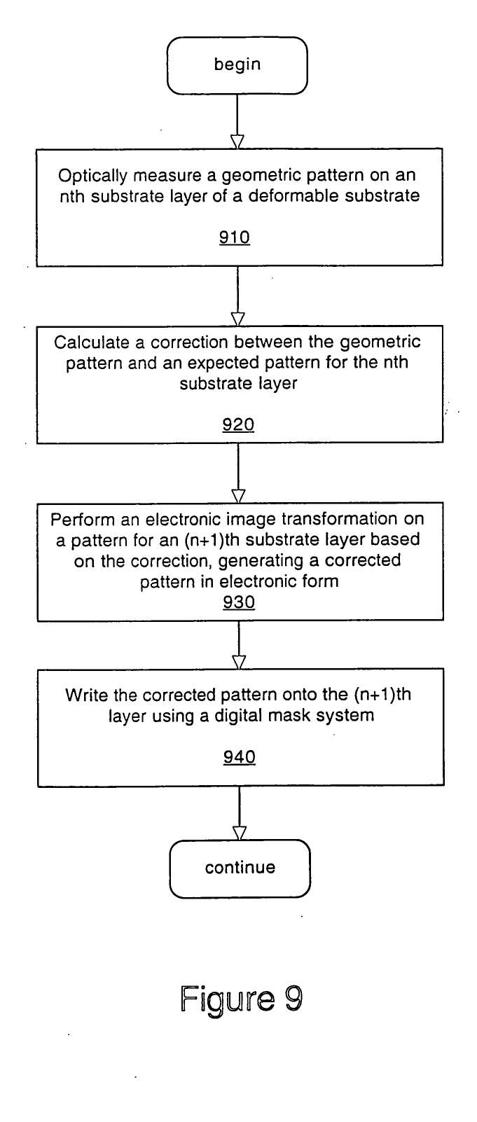

FIG. 9 is a computer controlled flow diagram summarizing a method for fabricating a circuit on a substrate in accordance with one embodiment of the present invention using system 50 for instance. At step 910, a geometric pattern deposited on an nth substrate layer of a deformable substrate is optically measured. The measuring device (e.g., optical detection device 58 of FIG. 5) may be a digital camera or a camera-type device suitable for capturing an image of a pattern deposited on a substrate.

At step 920 of FIG. 9, a correction is calculated based on the deviation between the geometric pattern on the nth substrate layer and the geometric pattern that was expected to be on the nth layer, according to one embodiment. The deviation may result from any physical event, but may result in one example from the processing of the substrate following the deposition of the nth layer, e.g., as a result of temperature and fabrication conditions to which the substrate is exposed. The processing typically exposes the substrate and pattern to temperatures in a range as to deform the deformable substrate, thus changing the originally deposited pattern (expected pattern). The correction may be a linear coordinate transform or a non-linear transform such as a spline function, for example.

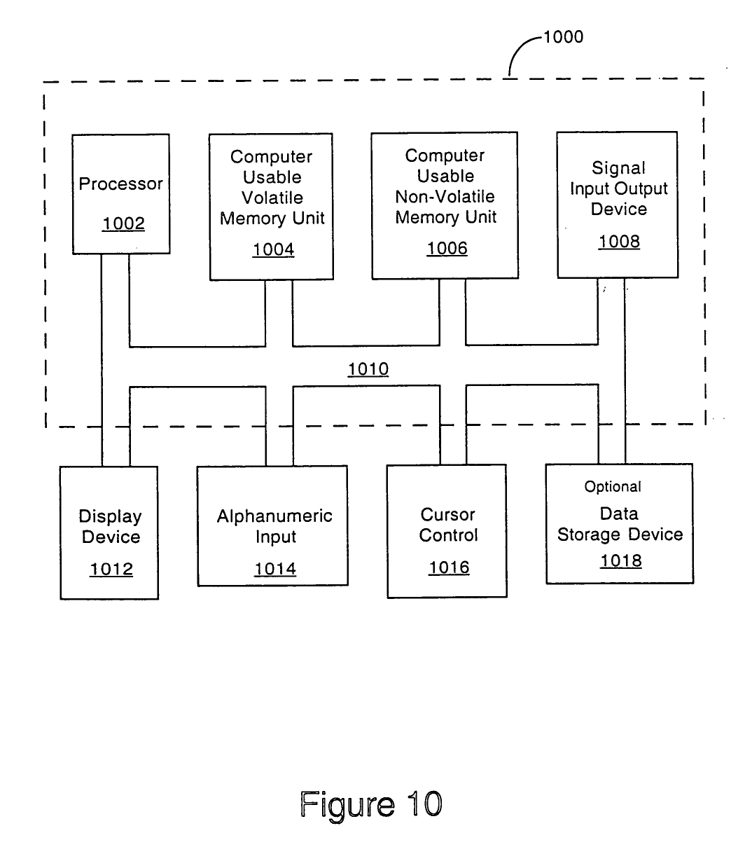

At step 930 of FIG. 9, an electronic image transformation is performed on a pattern for an (n+1)^{th} substrate layer based on the calculated correction, thus generating a corrected pattern in accordance with one embodiment of the present invention. The initial pattern and the corrected pattern may exist as electronic image data stored in computer readable memory of a computer system, e.g., computer system 1000 of FIG. 10. The corrected pattern is now compatible with the existing pattern of the nth layer, and should align appropriately when used to expose the (n+1)^{th} layer.

Importantly, at step 940, in accordance with one embodiment of the present invention, the corrected pattern is then fed to a programmable digital mask and used to write (expose) the (n+1)th layer using the digital mask system, such as digital micro-mirror device 52 of FIG. 5. This process is then continued, beginning with step 910 and following the appropriate processes (e.g., the process for generating an a-Si TFT array as shown in FIG. 1) until all of the layers are deposited for a given module.

Embodiments of the present invention may be comprised of computer-readable and computer-executable instructions that reside, for example, in computer-useable media of an electronic system, such as a peer system, a host computer system or an embedded system which may serve as a peer platform. FIG. 10 is a block diagram of an embodiment of an exemplary computer system 1000 used in accordance with the present invention. It should be appreciated that system 1000 is not strictly limited to be a computer system. As such, system 1000 of the present embodiment is well suited to be any type of computing device (e.g., server computer, portable computing device, desktop computer, etc.). Within the following discussions of the present invention, certain processes and steps are discussed that are realized, in one embodiment, as a series of instructions (e.g., software program) that reside within computer readable memory units of computer system 1000 and executed by a processor(s) of system 1000. When executed, the instructions cause computer 1000 to perform specific actions and exhibit specific behavior that is described in detail herein.

Computer system 1000 of FIG. 10 comprises an address/data bus 1010 for communicating information, one or more central processors 1002 coupled with bus 1010 for processing information and instructions. Central processor unit(s) 1002 may be a microprocessor or any other type of processor. The computer 1000 also includes data storage features such as a computer usable volatile memory unit 1004 (e.g., random access memory, static RAM, dynamic RAM, etc.) coupled with bus 1010 for storing information and instructions for central processor(s) 1002, a computer usable non-volatile memory unit 1006 (e.g., read only memory, programmable ROM, flash memory, EPROM, EEPROM, etc.) coupled with bus 1010 for storing static information and instructions for processor(s) 1002. System 1000 also includes one or more signal generating and receiving devices 1008 coupled with bus 1010 for enabling system 1000 to interface with other electronic devices and computer systems. The communication interface(s) 1008 of the present embodiment may include wired and/or wireless communication technology.

Computer system 1000 may include an optional alphanumeric input device 1014 including alphanumeric and function keys coupled to the bus 1010 for communicating information and command selections to the central processor(s) 1002. The computer 1000 includes an optional cursor control or cursor directing device 1016 coupled to the bus 1010 for communicating user input information and command selections to the central processor(s) 1002. The cursor-directing device 1016 may be implemented using a number of well known devices such as a mouse, a track-ball, a track-pad, an optical tracking device, and a touch screen, among others.

The system 1000 of FIG. 10 may also include one or more optional computer usable data storage devices 1018 such as a magnetic or optical disk and disk drive (e.g., hard drive or floppy diskette) coupled with bus 1010 for storing information and instructions. A display device 1012 is coupled to bus 1010 of system 1000 for displaying textual or graphical information, e.g., a graphical user interface, video and/or graphics. It should be appreciated that display device 1012 may be a cathode ray tube (CRT), flat panel liquid crystal display (LCD), field emission display (FED), plasma display or any other display device suitable for displaying video and/or graphic images and alphanumeric characters recognizable to a user.

Referring again to FIG. 9, in the present embodiment, step 920 the correction may be calculated by a computer system, such as computer system 1000. Similarly, the electronic image transformation of step 930 and the subsequent generation of a corrected pattern may be executed on computer systems, such as computer system 1000.

The foregoing descriptions of specific embodiments have been presented for purposes of illustration and description. They are not intended to be exhaustive or to limit the invention to the precise forms disclosed, and many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the claims appended hereto and their equivalents.

1. An automated method for patterning a plurality of electronic elements on a substrate comprising:
measuring an existing geometric pattern on an n^{th} layer of said substrate;
calculating a correction between said existing geometric pattern and an expected pattern for said n^{th} layer;
performing an image transformation on a pattern for an (n+1)^{th} layer of said substrate, based on said correction, to generate a corrected pattern; and
writing said corrected pattern onto said (n+1)^{th} layer of said substrate using a programmable digital mask system.

2. The method as described in claim 1 wherein said writing is performed by a writing component that comprises a radiation source.

3. The method as described in claim 2 wherein said writing comprises guiding radiation from said radiation source to said programmable digital mask system and from said programmable digital mask system to said substrate using an optical system.

4. The method as described in claim 2 wherein said radiation source comprises a pulsed laser source utilizing inter-pulse intervals.

5. The method as described in claim 2 wherein said radiation source is infrared light.

6. The method as described in claim 2 wherein said radiation source is ultraviolet light.

7. The method as described in claim 2 wherein said radiation source is x-ray.

8. The method as described in claim 1 wherein said measuring optical measuring performed by an optical measurement device.

9. The method as described in claim 1 wherein said existing geometric pattern comprises a plurality of alignment marks.

10. The method as described in claim 1 wherein said substrate is a deformable flexible substrate.

11. The method as described in claim 1 wherein said substrate is plastic.

12. The method as described in claim 1 wherein said substrate is metal.

13. The method as described in claim 1 wherein said substrate is paper.

14. The method as described in claim 1 wherein said substrate is glass.

15. The method as described in claim 1 wherein said correction is made by a linear coordinate transform.

16. The method as described in claim 1 wherein said correction is made by a non-linear spline function.

17. The method as described in claim 1 wherein said image transformation is performed locally for at least one segment of an electronic module.

18. The method as described in claim 1 wherein said image transformation is performed globally for an array of segments comprising an electronic module.

19. The method as described in claim 1 wherein said programmable digital mask system comprises an array of digital micro-mirror devices.

20. A method for patterning a plurality of electronic elements on a deformable substrate comprising:
a) calculating a correction between an existing geometric pattern on said substrate and an expected pattern for said n^{th} layer of said substrate;
b) performing an image transformation on a pattern for an (n+1)^{th} layer of said substrate based on said correction to generate a corrected pattern; and
c) controlling the writing of said corrected pattern onto said (n+1)^{th} layer of said substrate using a programmable digital mask and a radiation source.

21. The method as described in claim 20 wherein said writing comprises guiding radiation from said radiation source to said programmable digital mask and from said programmable digital mask to said deformable substrate.

22. The method as described in claim 20 wherein said radiation source comprises a pulsed laser source using inter-pulse intervals.

23. The method as described in claim 20 wherein said radiation source is infrared light.

24. The method as described in claim 20 wherein said radiation source is ultraviolet light.

25. The method as described in claim 20 wherein said radiation source is x-ray.

26. The method as described in claim 20 wherein said existing geometric pattern comprises a plurality of alignment marks.

27. The method as described in claim 20 wherein said existing geometric pattern comprises a plurality of electronic component features having a pitch of between 1-10 microns.

28. The method as described in claim 20 wherein said deformable substrate is plastic.

29. The method as described in claim 20 wherein said deformable substrate is metal.

30. The method as described in claim 20 wherein said deformable substrate is paper.

31. The method as described in claim 20 wherein said deformable substrate is glass.

32. The method as described in claim 20 wherein said correction is made by a linear coordinate transform.

33. The method as described in claim 20 wherein said correction is made by a non-linear spline function.

34. The method as described in claim 20 wherein said programmable digital mask system comprises an array of digital micro-mirror devices.

35. The method as described in claim 20 wherein said image transformation is performed locally for at least one segment of an electronic module.

36. The method as described in claim 20 wherein said image transformation is performed globally for an array of segments comprising an electronic module.

37. A computer-controlled method for patterning a substrate comprising:
exposing an image onto said substrate using an optical system and a programmable digital mask loaded with said image;
optically measuring an existing geometric pattern on an nth layer of said substrate;
calculating a correction between said existing geometric pattern and an expected pattern for said nth layer of said substrate using a computing device;
performing an image transformation on an electronic pattern for an (n+1)^{th} layer of said substrate, based on said correction, to generate an electronic corrected pattern stored in said computing device; and
writing said corrected pattern onto said (n+1)^{th} layer of said substrate.

38. The method as described in claim 37 wherein said radiation source comprises a pulsed laser source having inter-pulse intervals.

39. The method as described in claim 37 wherein said radiation source is infrared light.

40. The method as described in claim 37 wherein said radiation source is ultraviolet light.

41. The method as described in claim 37 wherein said radiation source is x-ray.

42. The method as described in claim 37 wherein said existing geometric pattern is a representation of said image and comprises a plurality of alignment marks.

43. The method as described in claim 37 wherein said existing geometric pattern comprises a plurality of electronic component features having a pitch of 1-10 microns.

44. The method as described in claim 37 wherein said substrate is deformable and is plastic.

45. The method as described in claim 37 wherein said substrate is deformable and is metal.

46. The method as described in claim 37 wherein said substrate is deformable and is paper.

47. The method as described in claim 37 wherein said substrate is deformable and is glass.

48. The method as described in claim 37 wherein said correction is made via a linear coordinate transform.

49. The method as described in claim 37 wherein said correction is made via a non-linear spline function.

50. The method as described in claim 37 wherein said programmable digital mask comprises an array of digital micro-mirror devices.

51. The method as described in claim 37 wherein said programmable digital mask comprises a liquid crystal light valve array.

52. The method as described in claim 37 wherein said image transformation is performed locally for at least one segment of an electronic module.

53. The method as described in claim 37 wherein said image transformation is performed globally for an array of segments comprising an electronic module.
